(19) United States
(12) Patent Application Publication
(10) Pub. No.: US 2020/0388750 A1
(43) Pub. Date: Dec. 10, 2020

(54) MAGNETIC DEVICES INCLUDING IRON-RHODIUM FILMS PROVIDING BI-STABLE MAGNETIC ORDER AT ROOM TEMPERATURE, MAGNETIC MEMORY SYSTEMS INCLUDING THE SAME AND RELATED METHODS OF OPERATION

(71) Applicant: Cornell University, Ithaca, NY (US)

(72) Inventors: Antonio Rodolph Bighetti Mei, Calabasas, CA (US); Gregory David Fuchs, Ithaca, NY (US); Isaiah Gray, Ithaca, NY (US)

(21) Appl. No.: 16/896,787

(22) Filed: Jun. 9, 2020

Related U.S. Application Data
(60) Provisional application No. 62/859,312, filed on Jun. 10, 2019.

(51) Int. Cl. H01L 43/10; H01L 27/22; H01L 43/02; H01L 43/08; G11C 11/16; H01F 10/32

(52) U.S. Cl. CPC H01L 43/10; H01L 27/222; H01L 43/02; H01F 10/32; G11C 11/161; G11C 11/1673; G11C 11/1675; H01L 43/08

(57) ABSTRACT

A magnetic device can include a substrate layer and an Fe₁₋ₓRhₓ film on the substrate layer, where x is in a range from about 0.47 to about 0.50, wherein a local region in the Fe₁₋ₓRhₓ film has a bistable magnetic order at a temperature between about 275K and about 325K. Films of Iron and Rhodium (FeRh) can provide both ferromagnetic (FM) and antiferromagnetic (AF) orders which are metastable at room temperature. For example, the composition of the Fe₁₋ₓRhₓ film can be controlled such that 0.47<x<0.50 so that after the magnetic order of the film (or a local region of the film) is established as AF or FM, the magnetic order can remain undisturbed while the temperature of the film varies within a range of room temperature.

### CLAIM FOR PRIORITY

This application claims priority to Provisional Application Ser. No. 62/859,312, titled Iron-Rhodium-Based Rewritable Magnetic Patterning Medium, filed in the U.S. Patent and Trademark Office on Jun. 10, 2019, the entire disclosure of which is hereby incorporated herein by reference.

### STATEMENT REGARDING FEDERALLY SPONSORED RESEARCH

This invention was made with government support from the National Science Foundation (NSF) under the E2CDA program (ECCS-1740136, DMR-1719875, DMR-1539918 and ECCS-1542081), and the Semiconductor Research Corporation under nCORE tasks 2758.001 and 2758.003. The government has certain rights in the invention.

### TECHNICAL FIELD

The technology disclosed in this patent document relates to magnetic materials for storing information.

### BACKGROUND

Magnetic materials are used in many electronic devices. For example, writable magnetic materials are used in disk drives and in some solid state non-volatile memories. Intermetallic Fe₁₋ₓRhₓ (B2, Pm 3m) exhibits a hysteretic anti-ferromagnetic/ferromagnetic transformation which has been used to produce, for example, composite multiferroics, magnetocaloric refrigerators, and memories operating based on antiferromagnetic state.

### SUMMARY

Embodiments according to the present invention can provide magnetic devices including Iron-Rhodium films providing bi-stable magnetic order at room temperature, magnetic memory systems including the same and related methods of operation. Pursuant to these embodiments, a magnetic device can include a substrate layer and a Fe₁₋ₓRhₓ film, on the substrate, where x is in a range from greater than 0.47 to less than 0.50 to provide a bistable magnetic order characterized by a difference in remanent magnetization of at least 40% for the Fe₁₋ₓRhₓ film at room temperature.

In some embodiments according to the invention, a magnetic memory system can include a magnetic memory including a plurality of addressable regions that can be configured to store data. An input buffer can be configured to store write data for writing to selected ones of the plurality of addressable regions using a write address. An output buffer can be configured to store read data retrieved from selected ones of the plurality of the addressable regions using a read address. A substrate can have an Fe₁₋ₓRhₓ film thereon where the Fe₁₋ₓRhₓ film provides the plurality of addressable regions, where x is in a range from greater than 0.47 to less than 0.50 to provide a bistable magnetic order for the Fe₁₋ₓRhₓ film at room temperature.

In some embodiments according to the invention, a magnetic device can include a substrate layer and an Fe₁₋ₓRhₓ film on the substrate layer, where x is in a range from about 0.47 to about 0.50, wherein a local region in the Fe₁₋ₓRhₓ film has a bistable magnetic order at a temperature between about 275K and about 325K.

In some embodiments according to the invention, a method of operating a magnetic device, can include heating a local region in an Fe₁₋ₓRhₓ film, where x is in a range from greater than 0.47 to less than 0.50, from about room temperature to at least about 350 degrees Kelvin to change a magnetic order of the local region from an antiferromagnetic (AF) order to a ferromagnetic (FM) order characterized by a difference in remanent magnetization of at least 40%, cooling the local region from about room temperature to less than about 275 degrees Kelvin to change the magnetic order of the local region from the FM order to the AF order, and heating the local region from about room temperature to at least about 350 degrees Kelvin to change the magnetic order of the local region from the AF order to the FM order.

In some embodiments according to the invention, a magnetic device can include a substrate layer and a Fe₁₋ₓRhₓ film, on the substrate that can be configured to provide a bistable magnetic order characterized by a difference in remanent magnetization of at least 5 times for the Fe₁₋ₓRhₓ film at room temperature.

### BRIEF DESCRIPTION OF THE DRAWINGS

FIG. 1 is an RBS spectrum of fully-dense phase-pure untwinned epitaxial B2 Fe_{0.52}Rh_{0.48}/MgO(001) layers with the iron and rhodium features indicated in some embodiments according to the invention.

FIG. 2 is a BF-TEM image showing the entire film cross-section of the layers of FIG. 1 in some embodiments according to the invention.

FIG. 3 is an SAED pattern of the cross-section of the layers of FIG. 1 in some embodiments according to the invention.

FIG. 4 is an XRD θ-2θ scan showing indexed reflections from the Fe_{0.52}Rh_{0.48} film and the substrate in some embodiments according to the invention.

FIG. 5 is an XRD co-rocking scan about the 001 film peak in some embodiments according to the invention.

FIG. 6 is a schematic depiction of room-temperature magnetic bistability of epitaxial Fe_{0.52}Rh_{0.48}/MgO(001) layers showing in plane magnetization M as a function of H field (clockwise), applied along FeRh [110], and temperature T (radial) during cooling to change the magnetic phase of the film from FM to AF in some embodiments according to the invention.

FIG. 7 is a schematic depiction of room-temperature magnetic bistability of epitaxial Fe_{0.52}Rh_{0.48}/MgO(001) layers showing in plane magnetization M as a function of H field (clockwise), applied along FeRh [110], and temperature T (radial) during heating to change the magnetic phase of the film from AF to FM in some embodiments according to the invention.

FIG. 8 is a graph of temperature-dependent remnant magnetization Mᵣ(T) during cooling (dotted) and heating (solid) in some embodiments according to the invention.

FIG. 9 is a graph of temperature-dependent resistivity ρ(T) during cooling (dotted) and heating (solid) in some embodiments according to the invention.

FIG. 10A shows photothermal control of exchange interactions of a device capable of real-time on-demand rewritable magnetic patterning at room temperature including a Nernst image of the device initialized in the AF phase at 295 K with highlighted regions representing different moments pointing right and left where weak contrast in the AF phase is due to uncompensated moments and residual ferromagnetism in some embodiments according to the invention.

FIG. 10B is a digital mask used to demonstrate photothermal magnetic patterning in some embodiments according to the invention.

FIGS. 10C and 10D are anomalous Nernst images collected at Happ=+1 kOe and Happ=−1 kOe, respectively where fields (applied along x) from the same region in FIG. 10A after writing the pattern in FIG. 10B given that both magnetic contrast and anisotropic transport effects contribute to image contrast in some embodiments according to the invention.

FIG. 10E is a resulting half-difference image of FIGS. 10C and 10D where the FM regions (dark) as clearly discernible from the AF background (light) in some embodiments according to the invention.

FIG. 10F shows half-differences of anomalous Nernst images of another device before writing, after writing letters spelling out the authors' affiliation, and after erasing by cooling with liquid nitrogen and warming back to room temperature where the contacts are along x, V_{ANE} represents M_{y} and Happ=1 kOe applied along ±y, which shows that FM patterns are fully erased by cooling with no discernible damage to the crystalline structure, as indicated by the recovery of the sample resistance to its value prior to writing in some embodiments according to the invention.

FIGS. 11A-11C are images illustrating ultrafast patterning of ferromagnetic regions including ANE half-difference images of a FeRh device before writing, after writing, and after erasing, respectively, where a 5×5 μm square was patterned using a single 3 ps laser pulse per 0.25×0.25 μm pixel although single pulses at 14 mJ cm⁻² fluence are sufficient to fully induce the phase transition, and the resulting FM patterns are again erasable by cooling below room temperature in some embodiments according to the invention.

FIG. 12 is a block diagram of a magnetic memory system including a plurality of addressable regions including a FeRh film used as a data storage layer in some embodiments according to the invention.

FIG. 13 is a block diagram of a magnetic memory system of FIG. 12 including a rotating media that includes a FeRh film used as a data storage layer that can operate using a write data element (to write data to the FeRh film) and a read data element (to read data from the FeRh film) in some embodiments according to the invention.

FIG. 14 is a block diagram of a magnetic memory system of FIG. 12 including an addressable memory array that includes a FeRh film used as a data storage layer that can operate using a write data element (to write data to the FeRh film) and a read data element (to read data from the FeRh film) in some embodiments according to the invention.

### DETAILED DESCRIPTION OF EMBODIMENTS ACCORDING TO THE INVENTION

As appreciated by the present inventor, in some embodiments according to the invention, films of Iron and Rhodium (FeRh) can provide both ferromagnetic (FM) and antiferromagnetic (AF) orders which are metastable at room temperature. For example, the composition of the Fe₁₋ₓRhₓ film can be controlled such that 0.47<x<0.50 (e.g., Fe_{0.52}Rh_{0.48}) so that after the magnetic order of the film (or a local region of the film) is established as AF or FM, the magnetic order can remain undisturbed while the temperature of the film varies within a range of room temperature. In some embodiments, the film's magnetic order can remain undisturbed while the temperature varies within a window of about +/−25K of room temperature.

The magnetic order can be changed, however, by increasing or cooling the film outside the window around room temperature. For example, as described herein in some embodiments, the magnetic order can be changed from AF to FM by heating the film to about 350K. When the film temperature is allowed to return to room temperature, the FM order is maintained despite subsequent temperature variations that fall within the window around room temperature. Similarly, the magnetic order can be changed from FM to AF by cooling the film to about 250K. When the film temperature is allowed to return to room temperature, the AF order can be maintained despite temperature variations that fall within the window of room temperature.

Accordingly, in some embodiments, different regions of the Fe₁₋ₓRhₓ film can simultaneously maintain different magnetic orders when at room temperature. Moreover, the simultaneously maintained magnetic orders can be relatively resistant to variations in temperature due to the hysteretic effect exhibited by the Fe₁₋ₓRhₓ films. Still further, the Fe₁₋ₓRhₓ film can simultaneously maintain different magnetic orders when at room temperature without the assistance of any other controlled effect the film, such as the application of an external magnetic field or a strain.

As further appreciated by the present inventor, the magnetic phase of the Fe₁₋ₓRhₓ film can be determine using a range of modalities. For example, in some embodiments according to the invention, the local region of the Fe₁₋ₓRhₓ film can heated by a thermal system, such as a laser or near field antenna, that couples moderate heating to the local region being read. The heated local region having the magnetic order can generate an electric field in response which is indicative of the FM magnetic phase, whereas no electric field is indicative of an AF magnetic phase. Other devices may be used to heat the local regions.

Still further in some embodiments, the magnetic phase of the Fe₁₋ₓRhₓ film can be determined using a voltage. In particular, the specific magnetic phases of the Fe₁₋ₓRhₓ film can provide different resistivities such that when a voltage is applied to the Fe₁₋ₓRhₓ film, the current generated by a region having the AF order is different than the current generated by a region having the FM order. Accordingly, a magnetic non-volatile memory system can utilize the Fe₁₋ₓRhₓ film as the data storage layer in the memory cells of the memory system. Each of the cells can be selected by an externally applied address, for the writing or reading of data to those selected memory cells. In some embodiments, a write operation can be carried out by heating or cooling the memory cells selected by the address to store the logical data (e.g., logical zero=AF order and logical 1=FM order). A read operation can be carried out also by applying a voltage to the memory cells selected by the address to thereby determine the resistivity of the selected cells to provide the read data (e.g., logical zero=high resistivity and logical 1=low resistivity).

In some embodiments, the read operation can also be carried out by heating the selected memory cells sufficiently so that the heated local region can generate an electric field which is indicative of the FM magnetic phase, or no electric field which is indicative of an AF magnetic phase. It will be understood that the heating during the read operation should be sufficient to elicit the response described above but less than the temperature required to change the magnetic order of the selected cells.

As further appreciated by the Fe₁₋ₓRhₓ film according to the invention can be formed on a material that provide a lattice match for the film. In some embodiments, the film can be MgO or piezoelectric material such as Pb(Zr,Ti)O3. It will be understood however, that although the lattice match may enable the formation of the Fe₁₋ₓRhₓ film with little strain, some strain may also allow the Fe₁₋ₓRhₓ film to operate according to the invention. For example, in some embodiments, a Fe₁₋ₓRhₓ film may have a strain that is about 1% or less.

As further appreciated by the present inventor, moderate heating (using for example a focused laser) can drive local regions controllably to the ferromagnetic phase, allowing arbitrary magnetic writing on the micrometer scale of ferromagnetic patterns within the antiferromagnetic matrix (i.e., FM orders within a matrix of AF order). The disclosed techniques and devices present opportunities for writing and erasing high fidelity magnetically-active nanostructured patterns that are of interest for magnonic crystals, artificial spin-ice lattices, and memory and logic devices. The formation of controlled patterns of magnetic structures within a nonmagnetic background can be used in devices including magnetic memory and logic devices, magnetic spin-ice lattices and enable the study of magnon propagation and magnonic gaps. Accordingly, also disclosed herein are techniques and devices for magnetic patterning that allows repeated creation and erasure of arbitrary shapes of thin film ferromagnetic structures.

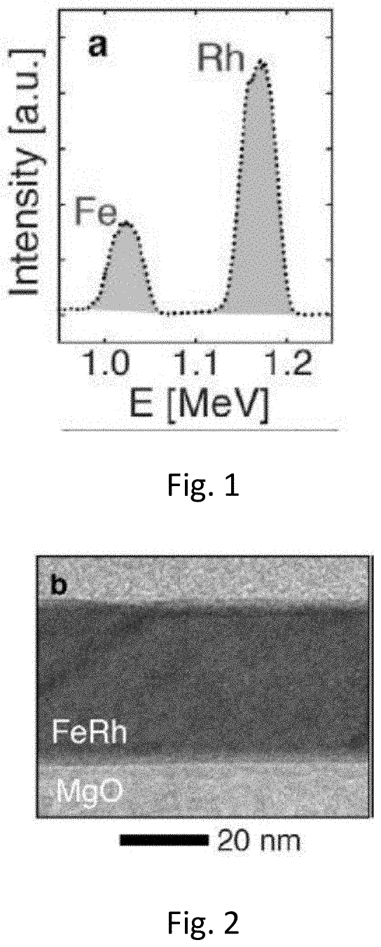

According to FIGS. 1-5 Fe1-xRhx films were grown epitaxially on single-crystalline (001)-oriented MgO substrates using molecular-beam epitaxy. The fraction x of rhodium in the films is tuned to 0.48 to lower the phase transition temperature from its value near 400 K for stoichiometric (x=0.5) FeRh to near room temperature. It will be understood that other types of formation may be used to provide a relatively order crystal growth, where resulting structure generates, for example, a Fe₁₋ₓRhₓ film having a crystalline structure characterized by an XRD ω-rocking curve FWHM value in a range between about 1.4 degrees to about 0.24 degrees as measured about the Fe₁₋ₓRhₓ 001 film reflection. Although a Fe_{0.52}Rh_{0.48} film was fabricated and evaluated herein. Fe₁₋ₓRhₓ films according to the invention can be any film where 0.47<x<0.50.

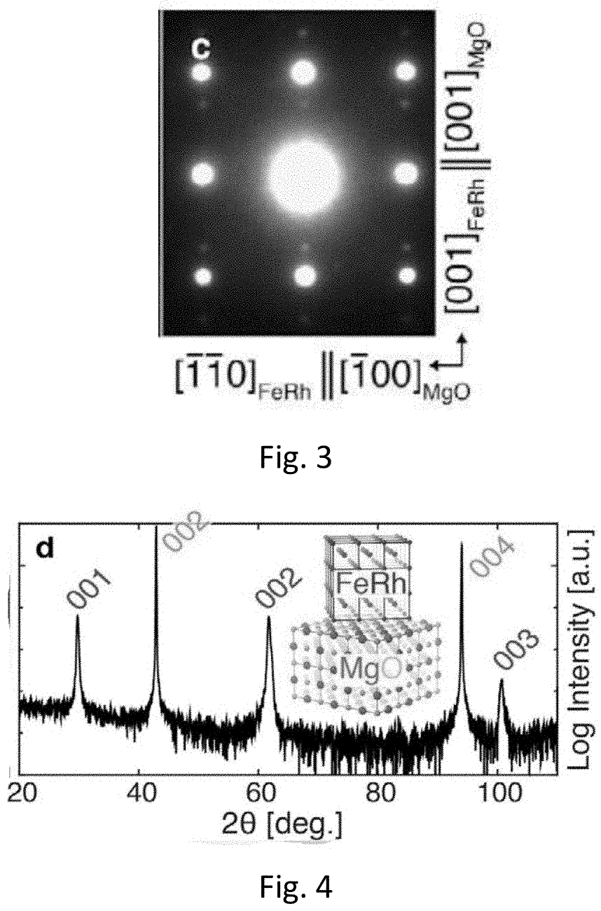

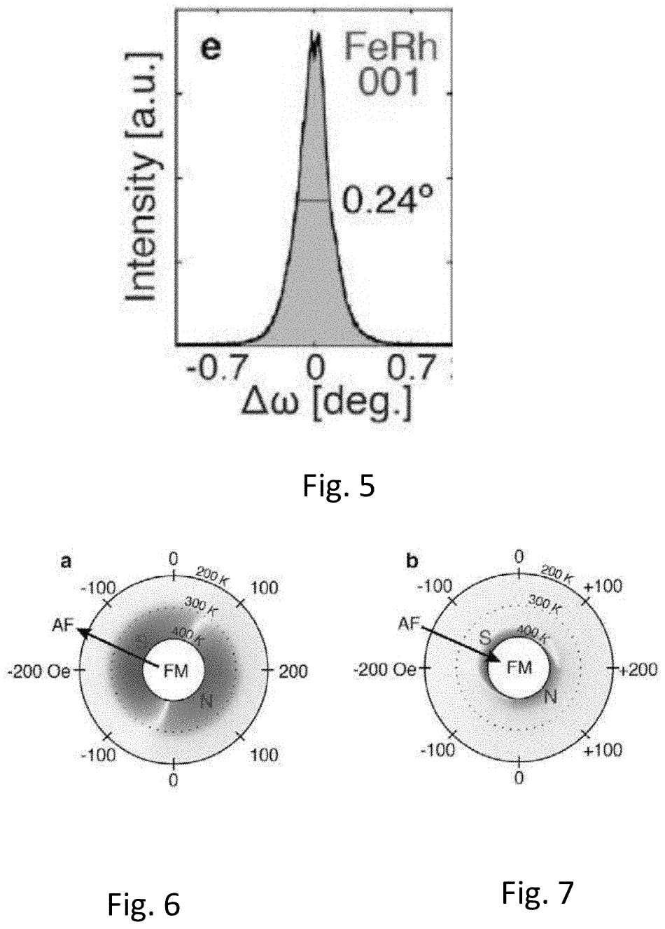

As appreciated by the present inventor, strong entropic competition between FM exchange and antiferromagnetic (AF) four-spin Fe—Rh—Fe interactions exist. A slight Rh deficiency enhances the nearest-neighbor FM exchange interaction and therefore decreases the transition temperature T_{C}. As shown in FIG. 1 film compositions were confirmed via Rutherford backscattering spec-trometry (RBS) measurements using the areal ratio of iron and rhodium spectral features. Cross-sectional bright-field transmission electron microscopy (BF-TEM) images in FIG. 2, selected area electron diffraction (SAED) patterns in FIG. 3, and X-ray diffraction (XRD) 9-29 scans in FIG. 4 demonstrate that the films were fully-dense phase-pure untwinned epitaxial Fe_{0.52}Rh_{0.48} layers with the B2 CsCl-structure and that the film lattice was rotated 45 in-plane with respect to the underlying B1 NaCl-structure MgO(001) substrate crystal: (001)_{Fe0.5,Rh0.48} II (001)_{MgO} and [110]_{Fe0.5,Rh0.48} II [100]_{MgO}. The structural quality of the films is established from the width of the w-rocking curve scans in FIG. 5.

The c/a ratio of out-of-plane and in-plane film lattice parameters was calculated from the 9-29 peak positions in the XRD scans assuming a coherently strained film. The resulting value of c/a=1.007 indicates that the film is tetragonally distorted and compressively strained by MgO. Since compressive strain increases T_{C}, the reduction in T_{C} observed in the samples can be attributed primarily to compositional rather than strain effects.

The room-temperature magnetic bistability of the fabricated epitaxial Fe_{0.52}Rh_{0.48}/MgO(001) layers was established through the combination of in-plane vibrating sample magnetometry (VSM) and electrical transport measurements. Magnetization measurements were collected as a function of temperature T and applied magnetic field H during cooling and heating are shown in FIGS. 6 and 7 where H is applied along Fe_{0.52}Rh_{0.48}[110]. At room temperature, the as-deposited films exhibits a field-dependent magnetic hysteresis characteristic of FM order as shown in FIG. 6 with measured saturation magnetizations Mₛ≈μ_{B}/f.u. and coercive fields H_{c}≈50 Oe.

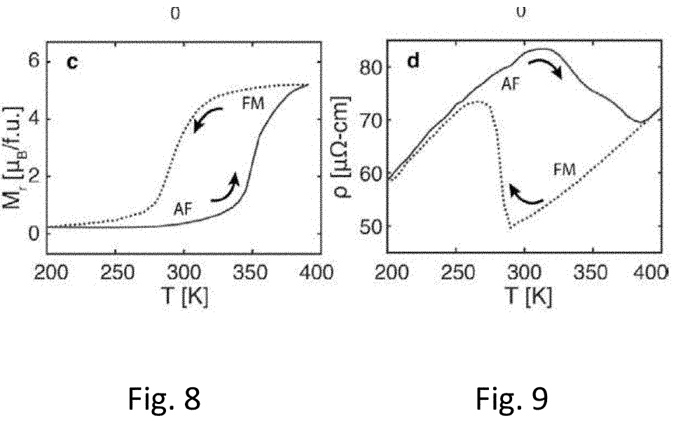

Cooling from 300 to 275 K suppresses the hysteresis associated with the FM state as shown in FIG. 6. In parallel, a fourfold reduction in remanent magnetization can be seen in FIG. 8 from Mᵣ=4 to 1 μ_{B}/f.u. and an approximate 50% increase in film resistivity in FIG. 9 from ρ=50 to 72 μΩ cm. These features are consistent with a magnetic transition, in which initially ferromagnetic Fe_{0.52}Rh_{0.48} layers adopt an antiferromagnetic configuration characterized by anti-aligned neighboring iron moments, decreased carrier densities, and increased scattering rates. With decreasing T below 250 K, remnant magnetizations decrease and saturate at ≈0.2 μ_{B}/f.u. as shown in FIG. 8.

On heating to 350 K, the field-dependent magnetic hysteresis shown in FIG. 7 and large remnant magnetization values shown in FIG. 8 defining the FM state are restored. The dissimilar temperatures during heating (350-385 K) and cooling (275-300 K) result in a thermal hysteresis and a window of bistability over which both FM and AF states can simultaneously coexist in the film. The transition temperature in the Fe_{0.52}Rh_{0.48} film is wider than in stoichiometric Fe_{0.50}Rh_{0.50}, which is consistent with previous composition-dependent studies of the phase transition that show increased transition width in both Rh-deficient and Rh-rich films. In both cases, disorder from point defects can broaden the transition.

As the temperature is raised from 350 to 400 K, the coercive field of the re-established FM state decreases from H_{c}≈200 to 50 Oe, which can be attributed to the enhanced coercivity at 350 K to exchange-coupling between recently-formed FM regions and the AF bulk, which decreases as the FM domains coalesce and the AF regions shrink at higher temperature. Over the same temperature range, resistivity values gradually decrease as a larger fraction of the sample transitions to the more conductive state associated with FM order as shown by FIG. 9. The gradual descent in film resistivity upon heating contrasts sharply with the abrupt jump observed upon cooling and reflects different kinetics in the heating and cooling branches of the transition.

Collectively, the in-plane magnetometry and transport measurements establish that the exchange interactions in epitaxial Fe_{0.52}Rh_{0.48}/MgO(001) films, under ambient conditions, exhibit bistable magnetic order. Switching between AF and FM orders can be achieved by heating and cooling over a practical temperature range, accessible to Peltier devices. Exchange interactions in FeRh films is discussed further in Structural, Magnetic, And Transport Properties Of Fe₁₋ₓRhₓ/MgO(001) Films Grown By Molecular-Beam Epitaxy, by Antonio B. Mei, et al. APPLIED PHYSICS LETTERS 113, 082403 (2018), which is incorporated herein by reference.

As further appreciated by the present inventor, the Fe₁₋ₓRhₓ films according to the present invention can use the designed magnetic bistability to provide magnetic patterning through the local photothermal control of exchange interactions. In particular, to interrogate the local magnetic order, a microscope configuration based on the anomalous Nernst effect (ANE) was used. This effect, which is the thermal analog of the anomalous Hall effect, can induce a detectable electric field given by:

\vec{E}_{ANE}(\vec{r})=N\vec{V}T(\vec{r})×μₒ\vec{M}(\vec{r})

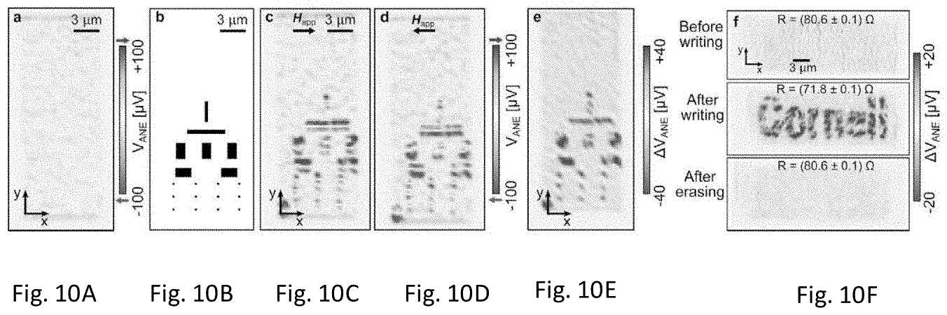

when a magnetic conductor with magnetization M(r) is subject to a thermal gradient ∇T (r); N is the anomalous Nernst coefficient of the material and μₒ is the permeability of free space. In some embodiments, thermal gradients of approximately 0.15 K nm⁻¹ (maximum temperature difference≈5 K) are produced primarily along the out-of-plane direction of the ≈35-nm-thick film by focusing 3 ps pulses from a mode-locked Al₂O₃:Ti laser pulse (λ=785 nm wavelength) with a fluence of 0.6 mJ cm⁻² onto a diffraction-limited spot on the sample surface. The laser fluence can be chosen to maximize the signal-to-noise of V_{ANE} (which increases with fluence) without perturbing the magnetic structure. The laser spot is then rastered across photolithographically defined device structures; in this geometry, the resulting E_{ANE} engenders a voltage V_{ANE} proportional to the in-plane component of M locally perpendicular to the device channel, which is Mₓ in FIGS. 10A-10E and M_{y} in FIG. 10F.

FIG. 10A shows a representative V_{ANE} map obtained at room temperature from a 10 mm′ 30 mm device initialized in the AF phase. The weak contrast observed is a combination of unpinned uncompensated moments that rotate with applied magnetic field and pinned uncompensated moments that are strongly exchange-coupled to the bulk Néel order. The uncompensated moments are consistent with the 0.2 μ_{B}/f.u. remnant magnetization detected in the AF regime using magnetometry as shown by FIG. 8.

To locally switch the magnetic order, the fluence was increased by a factor of 18 to 10.8 mJ cm⁻², which causes a peak temperature increase in the Fe_{0.52}Rh_{0.48} of ≈90 K. This temperature increase is sufficient to locally induce the FM phase while globally maintaining the sample at room temperature and in the AF state. According to some embodiments of the invention, because films are engineered to display magnetic bistability at room temperature, the induced FM regions persist even after photoheating when the region cools back to ambient temperature. Accordingly, FM regions can be written at high fluence and image those regions without perturbing the written pattern at low fluence.

Magnetic writing is demonstrated using the test pattern shown in FIG. 10B, which includes rectangles of varying aspect ratio as well as single pixel-size dots for determining the writing resolution. All magnetic writing is performed in zero magnetic field, in contrast to previous magnetic nanopatterning of an exchange-biased AF/FM bilayer. Each 0.25 μm×0.25 μm written pixel was exposed for 100 ms using a millisecond shutter. FIGS. 10C and 10D are ANE images collected from a patterned area with magnetic field Hₐₚₚ=1 kOe fields applied along the −x and +x directions, respectively. Written regions exhibit neighboring positive (darker) and negative (lighter) contrast resembling dipoles. The contrast contains two components. The first component arises from spatial inhomogeneity in the thermal conductivity, which is higher in the FM phase of FeRh than in the AF phase. Near an in-plane AF/FM boundary, there is an imperfect cancellation of the in-plane ordinary Seebeck electric field along +y and −y. The sign of the resulting Seebeck voltage depends on which side of the thermal discontinuity the laser is focused, leading to a strong dipole-like feature.

The second component giving rise to the contrast in FIGS. 10C and 10D is the ANE. To isolate this signal from the nonmagnetic charge Seebeck response, the half-difference between FIGS. 10C and 10D is computed by plotting (V_{ANE}(+Happ)−V_{ANE} (−Happ)/2. Happ=1 kOe saturates both the written FM regions and the unpinned uncompensated moments in the AF regions, while leaving charge Seebeck effect unchanged. Taking the half-difference between Happ=±1 kOe therefore isolates V_{ANE} and subtracts out nonmagnetic artifacts. The result, presented in FIG. 10E, shows FM regions (darker) within an AF background (lighter). The lighter contrast in the unwritten regions represents unpinned uncompensated moments. The observed FM shapes are consistent with the generating pattern and exhibit features with sub-micrometer dimensions. Because the same focused laser was used for writing and reading, the resolution of both processes is diffraction-limited by the 785 nm laser wavelength and approximately equal to the 650 nm spot size. Accordingly, in some embodiments, smaller patterns may be formed.

FIG. 10F shows that FM regions of arbitrary shape can be patterned and erased with no detectable damage to the crystalline structure. In a 10 μm×24 μm device fabricated from the same film as the device in FIG. 10A-10E, the image in the AF phase at 295 K was generated. Here the sample contacts are along x; therefore, V_{ANE}∝M_{y} and Hₐₚₚ is applied along ±y. FM regions in the shape of letters spelling out the inventors affiliation are laser-written and imaged; afterward the AF phase is reset by cooling the device below room temperature. Although cooling was provided by immersion of the sample in liquid nitrogen, the ≈250 K reset temperature can also be achieved with a Peltier device (ie., thermoelectric device). Subsequent imaging after warming to 295 K shows that the FM patterns are completely erased, illustrating the recovery of the sample resistance to its initial value. FM regions in Fe_{0.52}Rh_{0.48} can be laser-written and erased many times with no measurable degradation as measured by ANE imaging or resistivity, and furthermore that the written FM regions are stable for extended periods after writing. Erasure of FM patterns by cooling demonstrates that V_{ANE} in the written regions represents FM domains and not amorphous FeRh from laser-induced melting or crystallization as in phase-change optical recording media. Erasure by cooling also shows that the FM domains are due to the bistability of both AF phases at room temperature and not a reduced transition temperature from local damage to the atomic structure.

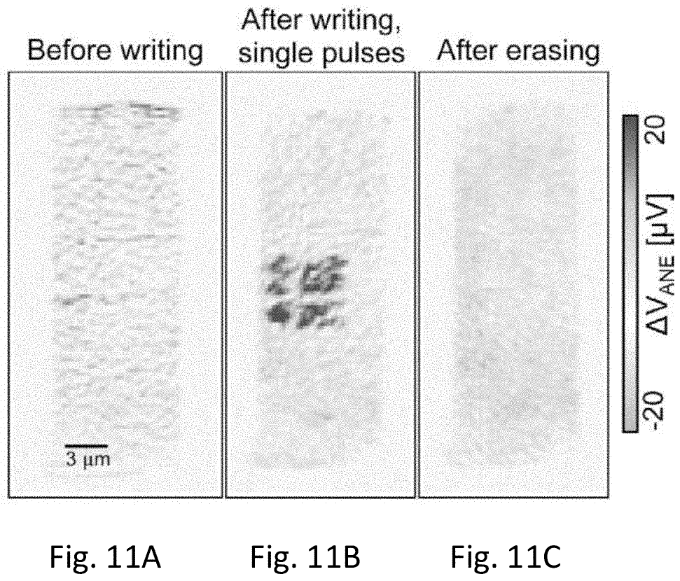

As further appreciated by the present inventor ultrafast magnetic writing can also be provided in embodiments according to the invention as illustrated, for example in FIG. 11 by patterning a 5×5 μm square with a single 3-ps laser pulse per pixel. This configuration is achieved using an electro-optic modulator and a synchronous countdown system. As in FIG. 10F, ANE images were acquired before writing, after writing, and after erasing. A fluence f=14 mJ cm⁻² is was used to fully induce the FM phase (as shown by the darker portions of FIG. 11B) with single pulses, a factor of 1.3 higher than the fluence employed using 100 ms write time. The image obtained after cooling shows that the FM patterns are still erasable by cooling and the higher fluence does not damage the sample.

As appreciated by the present inventor, previous pump-probe measurements of the laser-induced phase transition using femtosecond pulses indicate that ferromagnetic domains first nucleate in different orientations and then orient together toward the applied magnetic field. Time scales for nucleation and reorientation vary between 20-50 and 50-100 ps, respectively, depending on film composition and thickness. In some embodiments, the FeRh films reached peak temperature 20 ps after the pulse arrival. Accordingly, estimated writing time in the FeRh films is about 100 to 200 ps.

The Fe₁₋ₓRhₓ films evaluated herein were grown using molecular-beam epitaxy to thicknesses of ≈35 nm on single-crystalline (001)-oriented MgO substrates in a Veeco GEN10 system with a base pressure of 1×10⁻⁸ Torr. Iron (99.995% pure) and rhodium (99.95% pure) species were simultaneously supplied to the growth surface from independent effusion cells. Molecular fluxes were calibrated using X-ray reflectivity (XRR) and quartz crystal microbalances and configured to produce films with rhodium fractions x equal to 0.48. A substrate temperature of 420° C. (estimated from a thermocouple in indirect contact with the growth surface and concealed from incident molecular fluxes) was employed for film growth and subsequent half-hour-long in situ anneals. The anneal, which was performed immediately after film deposition, was designed to help order bcc Fe₁₋ₓRhₓ alloys into the B2 CsCl-structure intermetallic with iron and rhodium residing on distinct positions of the two-atom basis.

The compositions of the Fe₁₋ₓRhₓ films evaluated herein were determined using RBS using a probe comprised of 1.4 MeV He⁺ ions. The scattering geometry was defined by incident angle \acute{α}=7°, exit angle β=163°, and scattering angle Θ=170°. Spectra were integrated to a total accumulated ion dose of 15 μC. Film chemistry was determined by quantifying the area under iron and rhodium spectral features using an established procedure.

The structural characterizations of the Fe₁₋ₓRhₓ films evaluated herein were generated from X-ray-based measurements performed using a four-circle Philips X'pert MRD diffractometer operated with Cu_{Kα1} radiation of wavelength λ=0.15406 nm (Δλ/λ=10-4). The incident beam optics consisted of a four-bounce Ge 220 monochromator and a programmable 0.125-mm-thick Ni attenuator. For XRR and XRD scans, a 1/16° divergence slit and a Xe proportional detector were employed as receiving optics. For w-rocking curve measurements, the divergence slit was replaced with a Ge 220 triple-axis analyzer crystal, proving an angular resolution of 12 arc-sec.

BF-TEM images and SAED patterns were collected in an FEI F20 transmission electron microscope with a field-emission source operated at 200 kV. The specimen foils were prepared near the MgO[010] zone axis by cutting vertical film sections in a Thermo Fisher Helios G4 UX FIB. Initial milling was done using a 30 keV Ga⁺ focused ion beam. For final polishing, the ion energy was reduced to 5 keV.

The magnetic characterizations of the Fe₁₋ₓRhₓ films evaluated herein were based on the magnetic order of as-deposited Fe₁₋ₓRhₓ investigated in a Quantum Design physical property measurement system (PPMS). Temperature-dependent transport measurements were performed using the van der Pauw geometry with pressed-indium contacts by incrementally cycling the temperature in 5 K steps in the 200-395 K range. Magnetization M vs. applied magnetic field H data were collected over the same temperature window by equipping the PPMS setup with a VSM module and orienting the sample such that Fe₁₋ₓRhₓ [110] II H. At each temperature set point, the sample magnetization was recorded while the magnetic field is swept between ±200 Oe.

To write and image ferromagnetic patterns, an anomalous Nernst effect microscope was used. The local sample magnetization was transduced into an electrical voltage via a local thermal gradient. Local thermal gradients were generated using a pulsed Coherent Mira 900 Al₂O₃:Ti laser tuned to 785 nm wavelength. 3-ps-wide pulses and a repetition rate of 76 MHz (13 ns period) were employed. The laser was focused to a diffraction limited 650 nm-diameter spot using a 0.90 numerical aperture microscope objective. The laser was rastered using a 4f optical path in combination with a voice coil-controlled fast-steering mirror. To detect V_{ANE}, first, the laser-induced voltage pulse train was collected through a coplanar waveguide into a microwave transmission line and the pulses were amplified by 40 dB with 0.1-3 GHz bandwidth. The pulse train was then sent to the radio-frequency port of a DC-12 GHz electrical mixer, where it was mixed with a 600 ps-wide pulse train from an arbitrary waveform generator that was synchronized with the laser repetition rate. The mixer output voltage, V_{ANE}, was measured with a lock-in amplifier referenced to intensity modulation of the light with a photoelastic modulator. ANE images were acquired by signal-averaging for 125 ms at each pixel, using a lock-in time constant of 50 ms. At these settings, the signal-to-noise (V_{ANE} divided by electrical background noise) was 4.5 for uncompensated moments in the AF phase and 25 for written FM moments at room temperature.

Single-pulse writing was achieved using a Conoptics 350-160 electro-optic modulator in conjunction with a Model 305 synchronous countdown system. The electro-optic modulator was configured to admit a single pulse only when the countdown system was triggered by a TTL pulse and to block all other pulses. A National Instruments Multifunction I/O device was synchronized with the fast steering mirror and the shutter to generate a single TTL pulse for each position of the fast steering mirror. The extinction ratio of admitted to blocked pulses was measured to be 38 at f=14 mJ cm⁻² writing fluence. Therefore, the fluence of the blocked pulses was 0.4 mJ cm⁻² which had no influence on the phase transition.

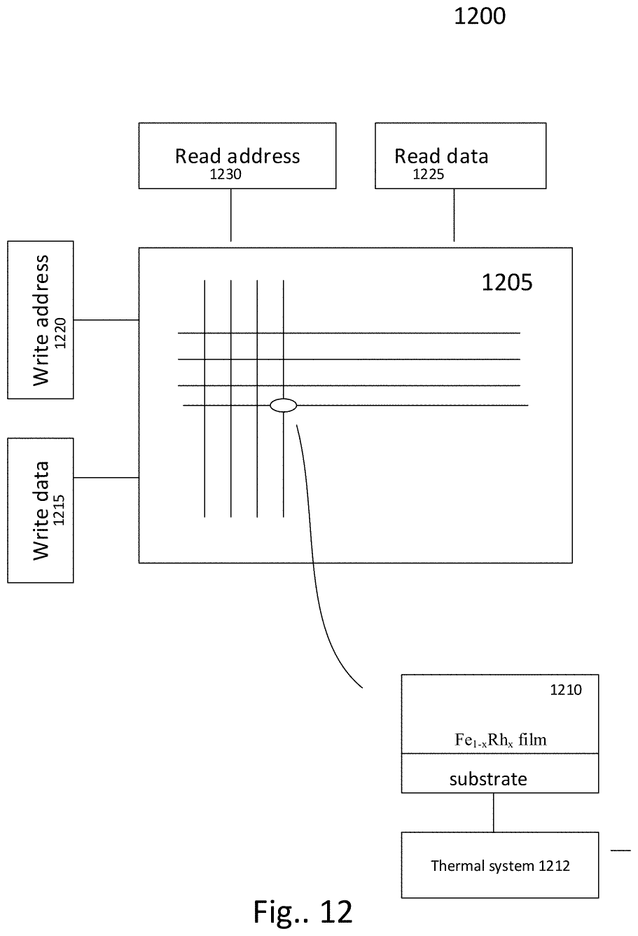

As further appreciated by the present inventor, embodiments according to the present invention can also enable magnetic memory systems including FeRh films as data storage layers. FIG. 12 is a block diagram of a magnetic memory system 1200 including a plurality of addressable regions 1205 with an Fe₁₋ₓRhₓ film 1210 used as a data storage layer in some embodiments according to the invention. According to FIG. 12, the magnetic memory system 1200 is configured such that a write address 1220 or a read address 1230 (stored in the respective right buffer or read buffer) can be used to selectively access ones of the plurality of addressable regions 1205. The write address 1220 can be used to select one of the plurality of addressable regions 1205 for the write operation wherein the write data 1215 can be stored at the selected ones of the addressable regions 1205. Furthermore, the read address 1230 can be used to select ones of the plurality of addressable regions 1205 from which read data 1225 is to be retrieve and provided in the output buffer. The write data 1215 and the write address 1220 are operatively coupled a thermal system 1212 which is used to heat the plurality of addressable regions 1205 selected by the write address 1220.

The thermal systems is thermally coupled to the selected ones of the plurality of addressable regions 1205 during a write operation based on the logical data that is to be written to each of the selected addressable regions 1205. For example, if a logical 1 corresponds to the FM magnetic order, the thermal system 1212 can heat the selected regions 1205 above room temperature up to a temperature that is sufficient to establish the FM magnetic order. In some embodiments, the thermal system 1212 can heat the selected regions 1205 to greater 350 degrees Kelvin (or more) in order to place the region 1205 in the FM magnetic order to store the logical 1. Once the write operation is complete, the thermal system 1212 can allow the respective region 1205 to return to room temperature wherein the FM magnetic order can remain stable despite variations in room temperature within a window, for example, of plus or minus 25 degrees Kelvin.

If, however, the data to be stored in the selected region 1205 is a logical 0 (corresponding to the AF magnetic order), the thermal system 1212 can cool the selected regions 1205 to below temperature that is sufficient to establish the AF magnetic order. In some embodiments, the thermal system 1212 can cool the selected regions 1205 to 275 degrees Kelvin (or less) in order to place the region 1205 that is to store the logical 0 in the AF magnetic order. Once the write operation is complete, the thermal system 1212 can allow the respective region 1205 to return to room temperature where in the AF magnetic order can remain stable despite variations in room temperature within a window, for example, of plus or minus 25 degrees Kelvin.

Still referring to FIG. 12, during a read operation, the read address 1230 selects the ones of the plurality of addressable regions 1205 which will be accessed to retrieve read data. The selected regions 1205 can be access using a variety of modalities, such as heat or voltage. For example, the selected regions can be heated above room temperature to generate an electric field response to the magnetic order of the region 1205. If the region 1205 is in the FM order, an electric field can be generated to indicate the logical 1 as the data. If, however, the region 1205 is in the AF order, an electric field may not be generated to indicate that the logical data is 0. It will be understood that the heat applied during the read operation should not be great enough to disturb the established magnetic order of the selected region 1205. For example, in some embodiments according to the invention the selected regions 1205 are heated above room temperature to less than 350 degrees Kelvin.

In view of the above, it will be understood that the thermal system 1212 can include a write data element that includes devices for heating and for cooling. The heating and cooling can be provided by any device that allows control over the regions 1205 to store the write data, such as a laser, a near field antenna, resistive heating, a thermoelectric device, and the like.

In other embodiments according to the invention, the selected regions can have a voltage applied across the film so as to generate a current that is proportional to the resistivity of the region. As discussed herein, when a region is in the FM magnetic order, that region has lower resistivity whereas when the region is in the AF magnetic order the region has a greater resistivity. Accordingly, the applied voltage will generate different current levels is response to the different magnetic orders. Accordingly, it will be understood that the thermal system 1212 can also include a read data element that includes devices for heating (such as a thermoelectric device, an applied voltage network, an applied magnetic field, or the like to generate a differentiable response from the selected region 1205 based on the magnetic order of the region 1205.

It will be further understood that the magnetic memory system may be configured to store two bits of data per cell. For example, In some embodiments according to the invention the magnetic memory system 1200 can be configured to store two logical states: the FM magnetic order or the AF magnetic order. In still further embodiments according to the invention, the magnetic memory system 1200 can be configured to store three logical states: a first state in the AF magnetic order, a second state in a first direction magnetic field (e.g., N) in the FM magnetic order and a third state in a second direction magnetic field (e.g., S) in the FM magnetic order. In further embodiments according to the invention, the magnetic memory system 1200 can be configured to store more than three states using a range of resistivity values associated with AF magnetic order and the FM magnetic order as described above for example in reference to FIG. 9.

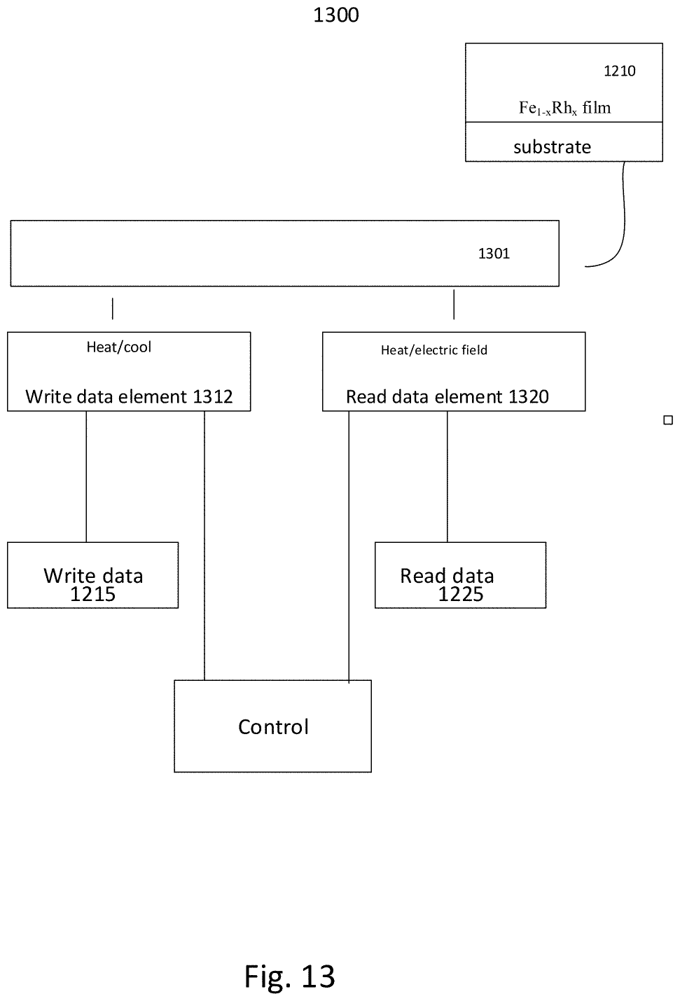

FIG. 13 is a block diagram of a magnetic memory system 1300 including a rotating media 1301 that includes a FeRh film used as a data storage layer that can operate using a write data element 1312 (to write data to the FeRh film) and a read data element 1320 (to read data from the FeRh film) in some embodiments according to the invention. According to FIG. 13, the write data element 1312 can include a device to heat or to cool the selected region 1205 depending on the data to be stored (as described above). The write data element 1312 can utilize devices configured to heat and cool the regions 1205 while remaining spaced apart from the selected regions 1205 so that the rotating media 1301 is free to move. The read data element 1320 can also include a device to heat the selected region 1205 and a device to detect an electric field while remaining spaced apart from the selected region 1205 as described above in reference to FIG. 12.

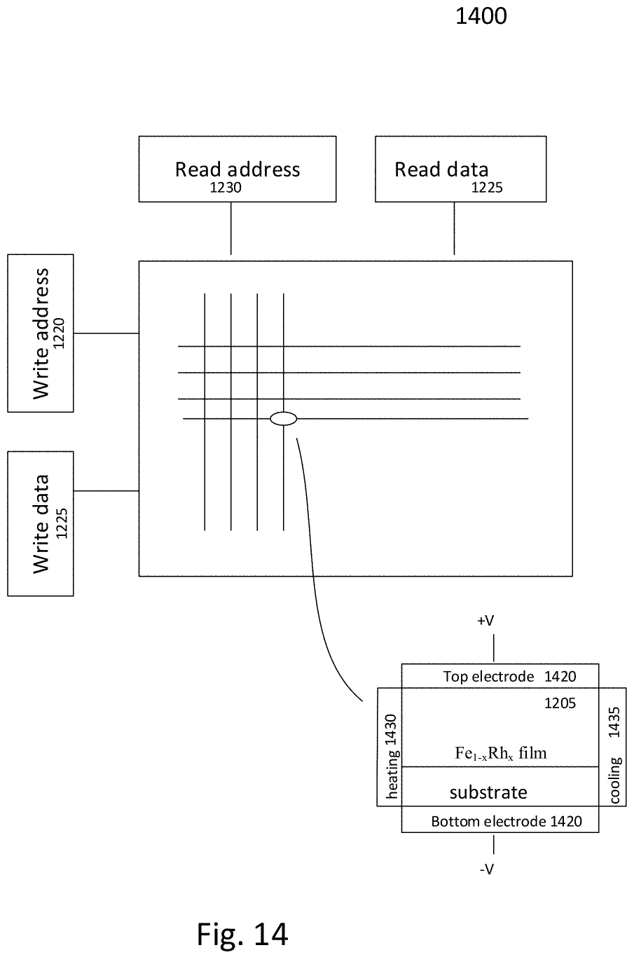

FIG. 14 is a block diagram of a magnetic memory system 1400 including an addressable memory array that includes an FeRh film used as a data storage layer that can operate using a write data element (to write data to the FeRh film) and a read data element (to read data from the FeRh film) in some embodiments according to the invention. According to FIG. 14, the data storage layer is coupled to resistive heating elements 1430 that are located in contact with or proximate to each of the addressable regions 1205 and operating under the control of the magnetic memory system 1400 so as to selectively heat addressed ones of the regions 1205.

The data storage layer is also coupled to thermoelectric devices 1435 that are located in contact with or proximate to each of the addressable regions 1205 and operating under the control of the magnetic memory system 1400 so as to selectively cool addressed ones of the regions 1205. The read data element 1420 can include a device to apply a voltage to electrodes that are in contact with (or proximate to) the film and operate under control of the magnetic memory system 1400 so as to selectively applied the voltage to the regions 1205 that are to be read. In some embodiments, the write data element and the read data element can be provided by the same structure where, for example, the electrodes are used to conduct a current through the film for the write operation and to apply the voltage for the read operation.

In this description like components have been given the same reference numerals, regardless of whether they are shown in different examples. To illustrate example(s) in a clear and concise manner, the drawings may not necessarily be to scale and certain features may be shown in somewhat schematic form. Features that are described and/or illustrated with respect to one example may be used in the same way or in a similar way in one or more other examples and/or in combination with or instead of the features of the other examples.

As used in the specification and claims, for the purposes of describing and defining the disclosure, the terms about and substantially are used to represent the inherent degree of uncertainty that may be attributed to any quantitative comparison, value, measurement, or other representation. The terms about and substantially are also used herein to represent the degree by which a quantitative representation may vary from a stated reference without resulting in a change in the basic function of the subject matter at issue. Comprise, include, and/or plural forms of each are open ended and include the listed parts and can include additional parts that are not listed. And/or is open-ended and includes one or more of the listed parts and combinations of the listed parts.

While this document contains many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

1. A magnetic device, comprising:
a substrate layer; and
a Fe₁₋ₓRhₓ film, on the substrate, where x is in a range from greater than 0.47 to less than 0.50 to provide a bistable magnetic order characterized by a difference in remanent magnetization of at least 40% for the Fe₁₋ₓRhₓ film at room temperature.

2. The magnetic device of claim 1 wherein the room temperature is in a range between about 275 degrees Kelvin and about 325 degrees Kelvin.

3. The magnetic device of claim 2 further comprising:
a thermal system, thermally coupled to the Fe₁₋ₓRhₓ film, the thermal system configured to heat the Fe₁₋ₓRhₓ film to greater than about 325 degrees Kelvin to establish a ferromagnetic (FM) order in the Fe₁₋ₓRhₓ film and configured to cool the Fe₁₋ₓRhₓ film to less than about 275 degrees Kelvin to establish an anti-ferromagnetic (AF) order in the Fe₁₋ₓRhₓ film.

4. The magnetic device of claim 1 wherein the Fe₁₋ₓRhₓ film has a crystalline structure characterized by an XRD ω-rocking curve FWHM value in a range between about 1.4 degrees to about 0.24 degrees as measured about the Fe₁₋ₓRhₓ 001 film reflection.

5. The magnetic device of claim 1 wherein the Fe₁₋ₓRhₓ film comprises an epitaxial Fe₁₋ₓRhₓ film.

6. The magnetic device of claim 1 wherein the substrate layer comprises a material that is lattice matched to the Fe₁₋ₓRhₓ film to within about 1% absolute strain.

7. The magnetic device of claim 6 wherein the substrate layer comprises MgO.

8. (canceled)

9. The magnetic device of claim 1 wherein the Fe₁₋ₓRhₓ film has a bistable magnetic order at a temperature between about 275 degrees Kelvin and about 325 degrees Kelvin.

10. The magnetic device of claim 1, wherein the Fe₁₋ₓRhₓ film maintains an antiferromagnetic (AF) magnetic order or a ferromagnetic (FM) magnetic order at about room temperature according to a hysteretic effect.

11. The magnetic device of claim 10 wherein the Fe₁₋ₓRhₓ film maintains a first direction of magnetization in the FM magnetic order at about room temperature according to a hysteretic effect or maintains a second direction of magnetization, opposite to the first direction of magnetization in the FM magnetic order at about room temperature according to the hysteretic effect.

12. The magnetic device of claim 10 wherein the Fe₁₋ₓRhₓ film exhibits a first resistivity in the AF magnetic order at about room temperature according to a hysteretic effect and exhibits a second resistivity in the FM magnetic order at about room temperature according to a hysteretic effect.

13. A magnetic memory system comprising:
a magnetic memory including a plurality of addressable regions configured to store data;
an input buffer configured to store write data for writing to selected ones of the plurality of addressable regions using a write address;
an output buffer configured to store read data retrieved from selected ones of the plurality of the addressable regions using a read address;
a substrate; and
an Fe₁₋ₓRhₓ film, on the substrate, the Fe₁₋ₓRhₓ film providing the plurality of addressable regions, where x is in a range from greater than 0.47 to less than 0.50 to provide a bistable magnetic order for the Fe₁₋ₓRhₓ film at room temperature.

14. The magnetic memory system of claim 13 wherein the room temperature is in a range between about 275 degrees Kelvin and about 325 degrees Kelvin.

15. The magnetic memory system of claim 14 further comprising:
a thermal system, thermally coupled to the Fe₁₋ₓRhₓ film, the thermal system configured to heat the Fe₁₋ₓRhₓ film to greater than room temperature to establish a ferromagnetic (FM) order in the Fe₁₋ₓRhₓ film and configured to cool the Fe₁₋ₓRhₓ film to less than room temperature to establish an anti-ferromagnetic (AF) order in the Fe₁₋ₓRhₓ film.

16. The magnetic memory system of claim 15 wherein the thermal system comprises:
a write data element operatively coupled to the input buffer and configured to heat the selected ones of the plurality of addressable regions in the Fe₁₋ₓRhₓ film addressed by the write address to greater than room temperature to establish the FM magnetic order responsive to the write data being in a first logical state; and
the write data element is configured to cool the selected ones of the plurality of addressable regions in the Fe₁₋ₓRhₓ film addressed by the read address to less than room temperature to establish the AF magnetic state responsive to the write data being in a second logical state.

17. The magnetic memory system of claim 16 wherein the write data element comprises a laser configured to heat the selected ones of the plurality of addressable regions and a thermoelectric device configured to cool selected ones of the plurality of addressable regions.

18. The magnetic memory system of claim 16 wherein the write data element comprises a near field antenna configured to heat the selected ones of the plurality of addressable regions.

19. The magnetic memory system of claim 16 wherein the write data element comprises:
a top electrode on a first surface of the Fe₁₋ₓRhₓ film; and
a bottom electrode on a second surface of the Fe₁₋ₓRhₓ film, wherein the selected ones of the plurality of addressable regions in the Fe₁₋ₓRhₓ film are heated by respective heating elements located proximate to the selected ones of the plurality of addressable regions.

20. The magnetic memory system of claim 16 the further comprising:
a read data element operatively coupled to the output buffer and configured to apply a voltage across the selected ones of the plurality of addressable regions in the Fe₁₋ₓRhₓ film to determine respective resistivities associated with the selected ones of the plurality of addressable regions to provide the read data.

21. The magnetic memory system of claim 16 further comprising:
a read data element operatively coupled to the output buffer and configured to heat the selected ones of the plurality of addressable regions in Fe₁₋ₓRhₓ film addressed by the read address to greater than room temperature but less than a temperature that is sufficient to disturb a present magnetic order of the selected ones of the plurality of addressable regions until the Fe₁₋ₓRhₓ film provides an electric field logically associated with the read data.

22.-27. (canceled)

28. A method of operating a magnetic device, the method comprising:
heating a local region in an Fe₁₋ₓRhₓ film, where x is in a range from greater than 0.47 to less than 0.50, from about room temperature to at least about 350 degrees Kelvin to change a magnetic order of the local region from an antiferromagnetic (AF) order to a ferromagnetic (FM) order characterized by a difference in remanent magnetization of at least 40%;
cooling the local region from about room temperature to less than about 275 degrees Kelvin to change the magnetic order of the local region from the FM order to the AF order; and
heating the local region from about room temperature to at least about 350 degrees Kelvin to change the magnetic order of the local region from the AF order to the FM order.

29.-41. (canceled)
